(19) United States
(12) Patent Application Publication
(10) Pub. No.: US 2008/0318343 A1
(43) Pub. Date: Dec. 25, 2008

(54) Wafer reclaim method based on wafer type

(76) Inventors: Krishna Vepa, Sunnyvale, CA (US); Yashraj Bhatnagar, Santa Clara, CA (US)

Correspondence Address: APPLIED MATERIALS/BSTZ;BLAKELY SOKOLOFF TAYLOR & ZAFMAN LLP, 1279 OAKMEAD PARKWAY, SUNNYVALE, CA, 94085-4040, US

(21) Appl. No.: 11/901,884

(22) Filed: Sep. 18, 2007

Related U.S. Application Data
(63) Continuation-in-part of application No. 11/823,061, filed on Jun. 25, 2007.

(51) Int. Cl. H01L 21/00

(52) U.S. Cl. 438/4; 257/E21.214

(57) ABSTRACT

A method for reclaiming a wafer is described. Embodiments of the invention describe a method in which an analytical measurement of a wafer surface is performed in order to determine a wafer type of the wafer. In an embodiment an XRF measurement is performed to determine the composition of a film disposed over a surface of the wafer. The XRF results are correlated with a wafer type. The wafer is then stripped in accordance with the wafer type.

### RELATED CASES

This application is a continuation-in-part of and claims priority to application Ser. No. 11/823,061 filed on Jun. 25, 2007.

### BACKGROUND OF THE INVENTION

1. Field of the Invention

The present invention relates to the field of reclamation and reuse of semiconductor material substrates. More particularly this invention relates to a method for reclaiming wafers at a reclaim factory based on wafer type.

2. Discussion of Related Art

The increasing process complexity and introduction of new materials to the field of integrated circuit (IC) fabrication has given rise to a greater number of processing steps; each of which must be tested for quality.

Test wafers including “dummy” or “control monitor” wafers are used to check the reliability of IC fabrication equipment. Dummy wafers are used to test new IC fabrication equipment prior to its implementation into the large-scale production process of ICs. For example, a dummy wafer is cycled through new film deposition or etch equipment, and the films disposed on the dummy wafer are then examined to determine if they meet certain specified criteria indicating that the fabrication process was properly performed. Only then is the equipment implemented into the production process. Thereafter, the dummy wafer may be discarded, or “reclaimed” by removing the deposited films and re-using the dummy wafer.

Once fabrication equipment is implemented into the production process, it must be periodically inspected by examining the fabricated ICs to ensure that it is functioning properly. Such quality assurance testing is typically performed on a daily basis, such as at the beginning of every working shift. During such testing, control monitor wafers are used in a trial process, such as film deposition, performed on the wafer. The control wafer is then examined to determine if it meets certain specified criteria indicating that the fabrication process was properly performed. Thereafter, the control wafer may be discarded (to protect intellectual property, for example), or “reclaimed” by removing the deposited films and re-using the control wafer.

All of this quality assurance testing requires the use of a large number of wafers and increases the total cost of IC fabrication. Customers will typically reclaim their wafers using their own equipment. However, each reclamation cycle roughens the wafer surface and after a few such cycles the wafers must be re-polished to meet fab specifications for such wafers to be used in their tools. These wafers are typically sent to a wafer reclaim vendor who provides the essential expertise and service for stripping and re-polishing the wafers to the customer's specifications and returning them to the customer for a service charge.

A typical wafer reclamation process includes multiple preliminary steps of incoming wafer inspection, ID detection, and sorting of the wafers into groups. The initial sorting of the wafers into groups is generally performed by a visual inspection. The grouped wafers are then subjected to removal steps such as grinding and/or etching particular materials, followed by polishing and cleaning. The process is finalized with a final multi-step outgoing wafer inspection to ensure that the proper amount of material was removed, and that customer specifications such as those for surface particles and wafer flatness are met.

The presence of copper films in the back-end processes has posed new problems to the wafer reclaim industry. Copper rapidly diffuses in silicon at relatively low temperatures and can cause the metal to form deep level traps for carriers. Reclaim vendors typically separate wafers that may have copper containing films during the initial visual inspection. However, residual copper containing wafers are inevitably mixed with non-copper containing wafer lots due to human error associated with the subjectivity of a visual inspection. As a result, copper bulk cross-contamination occurs during the reclaim process when a copper containing wafer is erroneously included in a non-copper containing wafer reclaim lot. The integrity of an entire reclaim wafer lot can be compromised by one misidentified copper containing wafer. Therefore, what is needed is a reasonable and cost-effective method for reclaiming wafers in which the risk of copper bulk cross-contamination is minimized.

### SUMMARY OF THE INVENTION

A method for reclaiming a wafer is disclosed. A wafer to be reclaimed is provided having a surface film disposed over a surface of the wafer. The wafer surface is then measured to determine the film composition. The wafer is sorted into a wafer type based on the results of the surface measurement. The surface film is then stripped form the wafer with a stripping solution specifically tailed to the wafer type.

### BRIEF DESCRIPTION OF THE DRAWINGS

FIG. 1 is an illustration of a method for reclaiming a wafer.

FIG. 2 is a side view illustration of an apparatus for incoming measuring of the wafer.

FIG. 3 is an illustration for a method of inspecting and measuring an incoming wafer and sorting the wafer into a wafer type.

FIG. 4A-4C are illustrations of stripping methods for back-end wafer types.

FIG. 5A-5C are illustrations of stripping methods for copper containing wafer types.

### DETAILED DESCRIPTION OF THE PRESENT INVENTION

Embodiments of the present invention disclose a method for reclaiming a wafer. In various embodiments, an apparatus for measurement of surface films and method of reclaiming a wafer are described with reference to figures. However, certain embodiments may be practiced without one or more of these specific details, or in combination with other known methods and materials. In the following description, numerous specific details are set forth, such as specific materials and processes, etc., in order to provide a thorough understanding of the present invention. In other instances, well-known semiconductor process manufacturing techniques have not been described in particular detail in order to not unnecessarily obscure the present invention. Reference throughout this specification to “one embodiment” means that a particular feature, structure, material, or characteristic described in connection with the embodiment is included in at least one embodiment of the invention. Thus, the appearances of the phrase “in one embodiment” in various places throughout this specification are not necessarily referring to the same embodiment of the invention. Furthermore, the particular features, structures, materials, or characteristics may be combined in any suitable manner in one or more embodiments.

Embodiments of the invention describe a method for reclaiming a wafer in which the surface of the wafer is analytically measured to determine the composition of films formed thereon. As used herein, the term “analytical” and variations thereof, is understood to mean identification of the component parts or constituent elements of a material. In a specific embodiment X-ray fluorescence (XRF) of the wafer surface is analytically measured to determine film composition. The results of the analytical surface measurement are correlated with a wafer type. In one embodiment, the wafer is then sorted into a group of wafers with a similar wafer type and the group of wafers is stripped with a stripping solution determined by the wafer type. In an alternative embodiment, the wafer is processed individually after correlating the results of the analytical surface measurement with a wafer type and sorting the wafer. In an embodiment, wafers are sorted and processed as either a copper film containing wafer type or a non-copper film containing wafer type.

In one aspect, utilizing embodiments of the invention, a reclaim vendor can identify and sort out copper film containing wafers at an initial stage through analytical identification, thereby eliminating the subjectivity and inherent human error associated with sorting of wafers based upon a visual inspection. Utilizing embodiments of the invention, a reclaim vendor can not only eliminate the inherent human error in identifying copper surface films, a reclaim vendor can also reliably identify wafers which contain copper films buried beneath an additional surface film. Such sub-surface copper films are also called stealth copper films because they may not be visible from a visual inspection. As a result the risk of copper bulk cross-contamination is significantly reduced when utilizing embodiments of the present invention.

In another aspect, embodiments of the invention improve the efficiency of the wafer reclaim process by improving the incoming and/or in-process inspection by analytically measuring wafer surface film composition. By doing so the wafers may be sorted according to chemical composition of the films deposited thereon prior to the stripping process, and the stripping process may be specially tailored to wafer composition, thus minimizing the need for re-working wafers which do not strip well in the first instance.

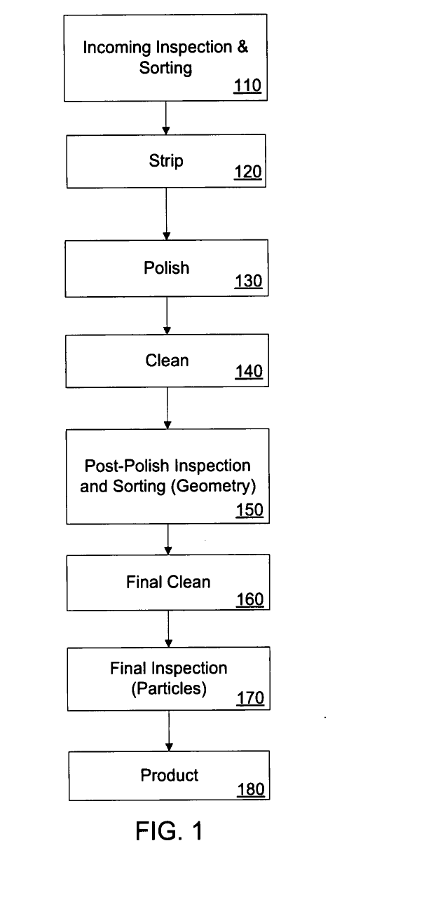

FIG. 1 is an illustration of a method for reclaiming a wafer. As shown in block 110 incoming wafers are inspected and sorted based on wafer type. The inspection and sorting operation 110 may be aided by visual inspection of the wafer by the operator, wafer process information provided by the customer, and wafer measurements. In an embodiment the x-ray fluorescence is measured and correlated with a wafer type. An analytical measurement of the x-ray fluorescence measurement allows the operator to distinguish between the types of metal films present, and to identify the presence of films that would be difficult to detect in a visual inspection only. In an embodiment, x-ray fluorescence is measured in order to determine if a copper film is present on the wafer. In an embodiment x-ray fluorescence is measured in order to determine if a copper film is present buried beneath an additional surface film, the presence of which might not be detectible in a visual inspection only.

In an embodiment the refractive index of a surface film is measured. An analytical measurement of the refractive index allows the operator to correlate the measured refractive index with that of a known film composition, something that a reclaim vendor may not be able to do accurately and consistently with a visual inspection only. For example, the reclaim vendor may sort the wafers into separate groups for films such as oxide, nitride, low-k, and even bare wafers, all of which may not be accurately and consistently distinguishable based on a visual inspection only.

In an embodiment, the incoming wafer ID (such as T7 code) is read and the wafer thickness is measured during the initial inspection and sorting operation 110. Wafers not possessing a wafer ID or a minimum thickness are sorted out at this point. In an embodiment, wafers possessing a thickness less than approximately 650 μm are considered too thin to reclaim.

After an initial inspection and sorting, the wafers are subjected to a specifically tailored stripping process for the specific materials films present or not present, as shown in block 120. During the stripping process all films present on the wafer surface are removed to expose the bare wafer. Over stripping the wafers in acid baths roughens the wafer surface and requires additional polishing time at step 130. Accordingly, utilizing embodiments of the present invention, a reclaim vendor may avoid problems such as unnecessarily over stripping the wafers because the chemistry of the surface films is known and the stripping solutions and processes are tailored for the specific film chemistries present. In addition, knowledge of the film type enables the reclaim vendor to ensure that appropriate stripping processes are applied to the appropriate wafers, thus reducing the likelihood of having to re-work (re-strip) wafers. Thus, determining the chemistry of the deposited layers at an early stage through methods such as refractive index or x-ray fluorescence can shorten the overall reclaim cycle time.

The wafers are then polished as shown in block 130. Polishing may be single-side polishing (SSP), back-side polishing (BSP), or double-side polishing (DSP) depending on wafer type and/or customer specifications. The polished wafers are then thoroughly cleaned in an SC1/SC2 cleaning process and dried at block 140. The wafers are then visually inspected for microscratches at block 150. Additionally, the wafers can be tested for flatness, thickness, bow/warp to verify the processed wafers are within customer specification. Wafers passing the inspection are then given a final clean in a single wafer cleaning apparatus at block 160. The final cleaned wafers are given a final particle inspection at block 170, and then dried, sorted, and packaged as final reclaim product at block 180.

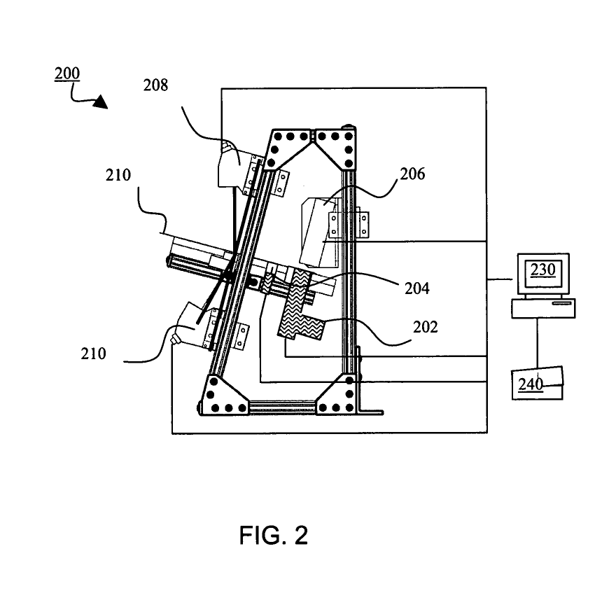

FIG. 2 is a side view illustration of one embodiment of a wafer inspection apparatus for measuring incoming wafers. In an embodiment, wafer inspection apparatus 200 includes an XRF analyzer 202, refractive index sensor 204, wafer ID reader 206, upper thickness monitor 208, and lower thickness monitor 210. XRF analyzer 202 may be any commercially available unit capable of nondestructive testing, such as the Thermo Scientific NITON XLt series portable XRF analyzer, available from NITON Analyzers HQ (Billerica, Mass.). Preferably, XRF analyzer 202 is capable of measuring the composition of metal and metal alloy layers contained within the surface layers of a wafer in a matter of seconds.

In one embodiment, the measurement face of XRF analyzer 194 is positioned as close as possible to the bottom surface of wafer 220 without touching wafer 220. In one embodiment, the bottom surface of wafer 220 is the device-side surface, or the surface containing surface films to be removed. In one embodiment, the distance separating the measurement face of XRF analyzer 202 and the wafer 220 is less than approximately 0.1 mm. However, it is to be appreciated that XRF analyzer 194 can also be operated independently, and need not be attached to apparatus 200.

In one embodiment, the operator may simultaneously measure the wafer surface XRF, refractive index, wafer ID, and wafer thickness. As shown in FIG. 2, the XRF analyzer 202, refractive index sensor, 204, the wafer ID reader 206 and thickness monitors 208 and 210 can all be connected to a computer 230 and foot-switch 240. The computer 230 may for example be a local computer or a host computer connected through the factory manufacturing enhancement system (MES) which is a database for the entire factory automation. The operator may trigger simultaneous measuring of the wafer surface XRF, refractive index, wafer ID, and wafer thickness by triggering a foot-switch 240. One advantage of the foot-switch 240 is that this allows the operator's hands to remain free for handling wafers and performing other functions. However, it is to be appreciated that apparatus 200 can also be operated by a fully automated system.

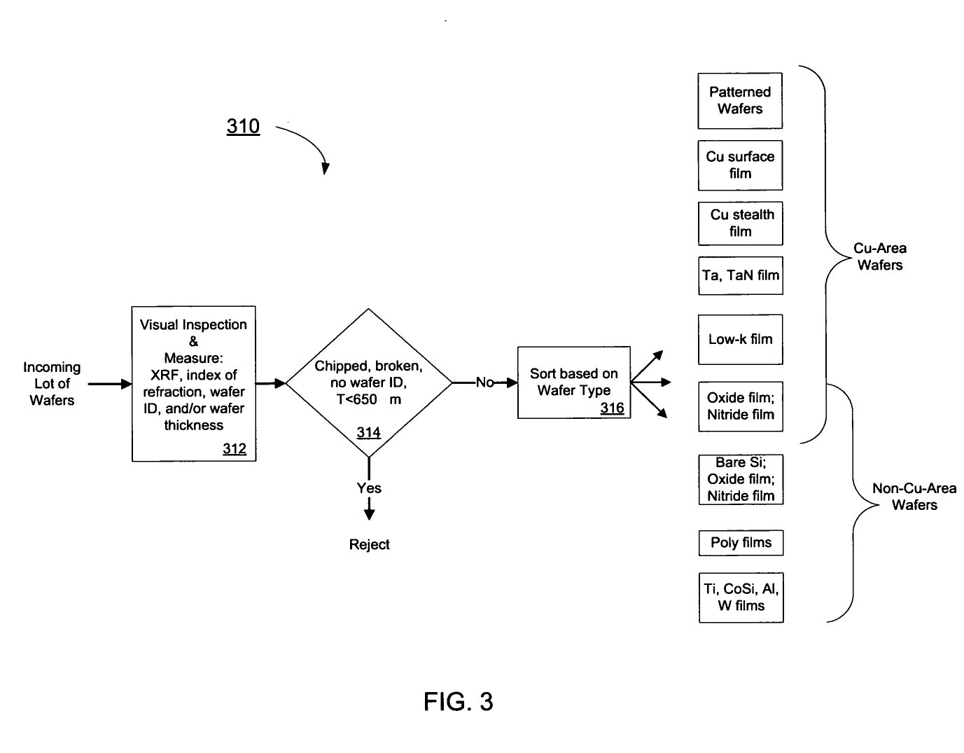

FIG. 3 provides a detailed process 310 of the incoming inspection and sorting operation of block 110 in accordance with an embodiment of then invention. As shown in block 312 the inspection and sorting operation may be aided by visual inspection by the operator, wafer process information provided by the customer, and wafer measurements. Wafer measurements may include reading the wafer ID (such as T7 code), measuring the wafer thickness, measuring wafer surface XRF, and measuring wafer surface film index of refraction.

Then at block 314 non-conforming wafers are rejected from the reclamation process. For example, chipped or broken wafers, or wafers with no wafer ID are sorted out of the process. Additionally, wafers which are too thin for reclaiming may be sorted out at this point. In an embodiment, wafers possessing a thickness less than approximately 650 μm are considered too thin to reclaim and are sorted out.

Wafers which are not sorted out of the reclamation process at block 314 are then sorted based on wafer type at block 316. It is to be appreciated that analytical measurement of the wafer surface allows a reclaim vendor to determine the composition of films formed on the wafer without the subjectivity and guess work associated with making such a determination by visual inspection alone. In addition, the compositions of any films lying beneath the top surface film are also determined.

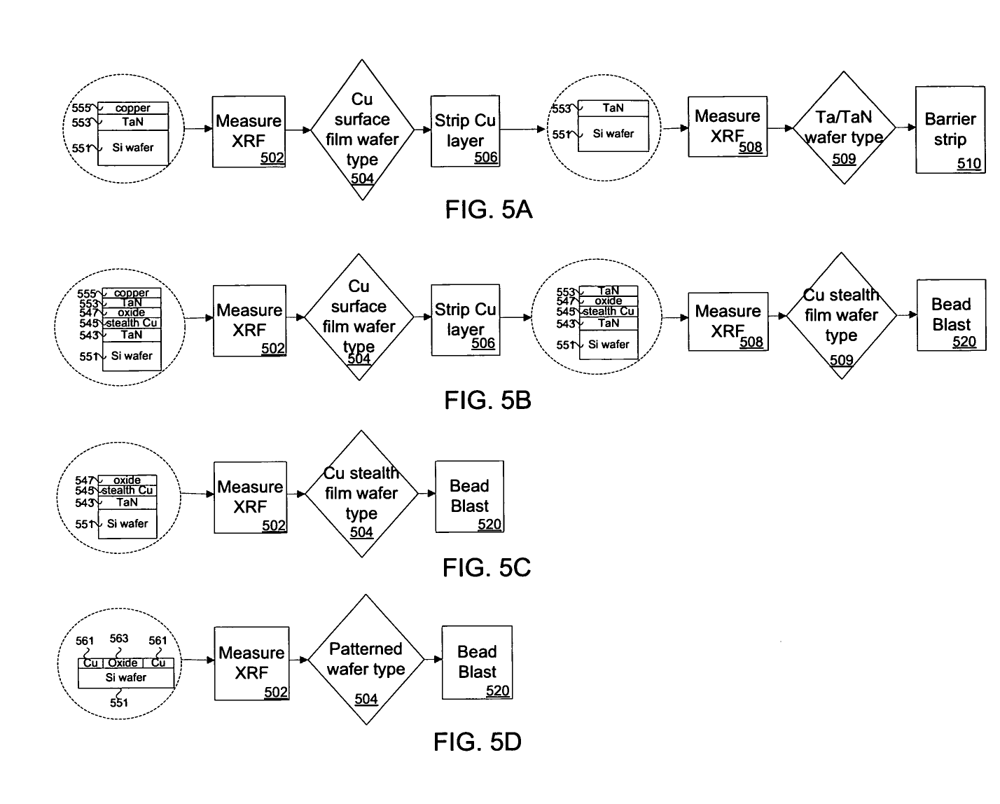

In an embodiment the wafers are sorted as either a copper film containing wafer type or non-copper film containing wafer type. The copper film containing wafer type may include, for example, wafers having a copper surface film (see FIG. 5A), copper stealth (sub-surface) film (see FIG. 5B and FIG. 5C), and patterned wafers (see FIG. 5D). A patterned wafer type is a wafer which includes at least one film disposed on the wafer surface which has been through lithographic and etching steps to form a pattern, such as a circuit pattern. The circuit patterns and metal lines in patterned wafers often contain copper. A stealth copper film wafer type contains a copper film disposed above the wafer substrate surface but beneath a second film. In another embodiment, the wafers are sorted by more specific wafer types including, but not limited to, Ta/TaN films, low-k carbon containing films (such as Black Diamond™ and BLOk™), oxide/nitride films, bare silicon wafer, polysilicon film, CoSi film, and Ti/Al/W films.

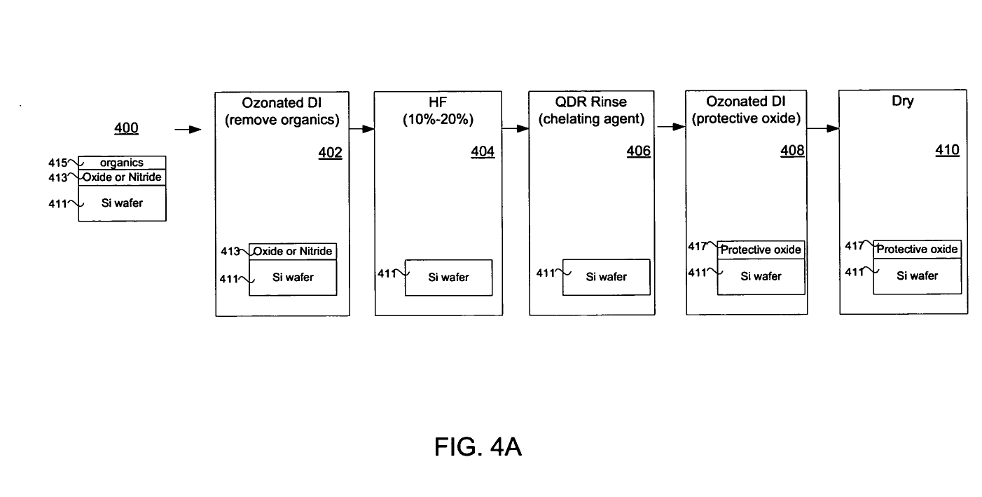

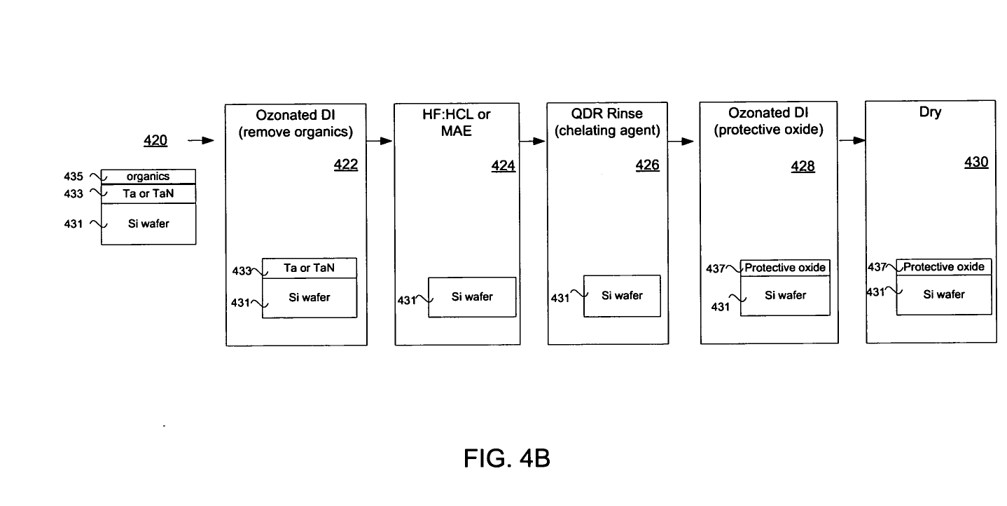

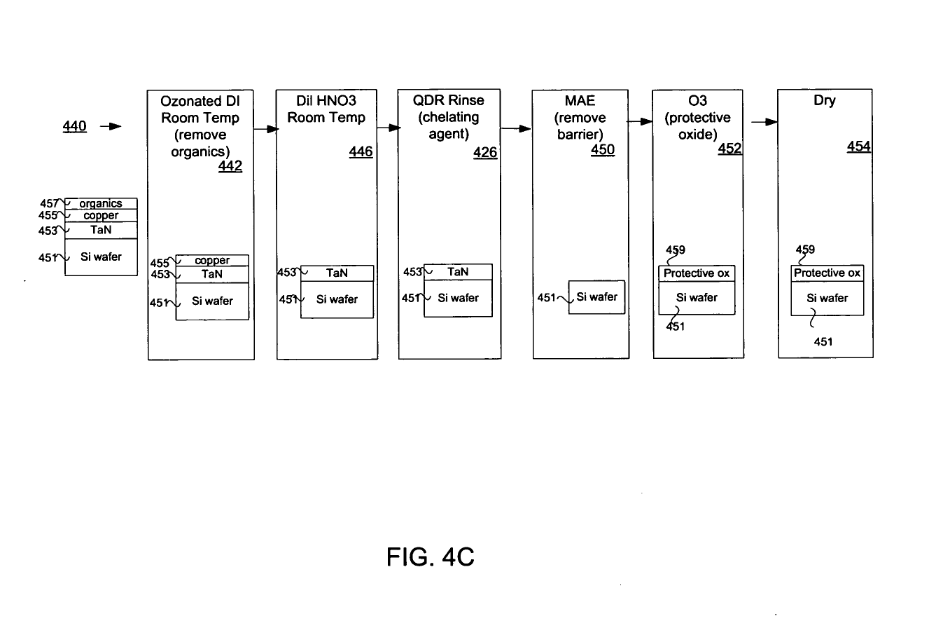

FIGS. 4A-4C are illustrations of stripping methods for back-end (copper area) wafer types according to embodiments of the invention. As shown in FIGS. 4A-4C, by sorting and processing the wafers as wafer types that are more specific than generally copper area (back-end processes where a copper film may be present) or non-copper area (front-end processes), the stripping methods can be tailored to the specific films present to both avoid any unnecessary etching steps or re-working, and minimize the risk of copper bulk cross-contamination.

As shown in FIG. 4A, an oxide/nitride wafer type is stripped according to method 400. In an exemplary embodiment, an oxide/nitride wafer type includes a silicon wafer 411 with an oxide or nitride film 413 disposed thereon. A residual organic film 415, such as photoresist, may be disposed over film 413. At block 402 a DI water solution comprising dissolved ozone (O3) is applied to the oxide/nitride wafer type to remove any residual organic films 415. In one embodiment, the DI water solution comprises 10 ppm to 20 ppm dissolved O3. The oxide/nitride film 413 is then stripped using a dilute HF solution with approximately 10%-20% HF in solution at block 404. The wafer is then rinsed with a solution comprising a chelating agent, such as EDTA, at block 406. The chelating agent functions to additionally bind any free metal ions that may be present in the rinse solution. The wafer is then exposed to a second DI water solution comprising dissolved O3 at block 408 to grow a protective oxide film 417 in order to protect the hydrophobic silicon wafer 411 surface from attracting particles. In an embodiment, the protective oxide film 417 is temporary and will eventually be removed in the subsequent polishing operation. The wafer is then dried at block 410.

As shown in FIG. 4B, a Ta/TaN wafer type is stripped according to method 420. In an exemplary embodiment, a Ta/TaN wafer type includes a silicon wafer 431 with a Ta or TaN film 433 disposed thereon. A residual organic film 435, such as photoresist, may be disposed over film 433. At block 422 a DI water solution comprising dissolved O3 (10 ppm to 20 ppm) is applied to the Ta/TaN wafer type to remove any residual organic film 435. The Ta/TaN film 433 is then stripped at block 424 using a mixed acid etchant comprising either an HF:HCI (hydrofluoric acid:hydrochloric acid) mixture; or dilute HNO3:HF:HAc (nitric acid:hydrofluoric acid: acetic acid) mixture containing approximately 30% DI water. The wafer is then rinsed with a solution comprising a chelating agent, such as EDTA, at block 426. The wafer is then exposed to a second DI water solution comprising dissolved O3 at block 428 to grow a protective oxide film 437, and dried at block 430.

As shown in FIG. 4C, a Cu/TaN wafer type is stripped according to method 440. In an exemplary embodiment, a Cu/TaN wafer type includes a silicon wafer 451 with a TaN film 453 disposed over the silicon wafer 451. A surface copper film 455 is disposed over the TaN film 453, and a residual organic film 435, such as photoresist, may be disposed over film 455. At block 442 a DI water solution comprising dissolved O3 is applied to the Cu/TaN wafer type to remove any residual organic films 457 such as photoresist. In an embodiment the DI water solution comprising dissolved O3 (10 ppm to 20 ppm) is applied at room temperature in order to minimize any interdiffusion of copper into the wafer 451. The copper film 455 is stripped at block 446 using a dilute HNO3 solution to expose the TaN film 453. In an embodiment, the copper stripping solution is applied at room temperature in order to minimize any interdiffusion of copper into the wafer 451. The wafer is then exposed to a mixed acid etchant such as a dilute HNO3:HF:HAc (nitric acid:hydrofluoric acid:acetic acid) mixture containing approximately 30% DI water in order to remove the TaN barrier layer 453 at block 450. The wafer is then exposed to a second Dl water solution comprising dissolved O3 at block 452 to grow a protective oxide layer 459, and dried at block 454.

Additional wafer types that are back-end or copper area wafer types include patterned wafer types (see FIG. 5D), stealth copper film wafer types (see FIGS. 5B and 5C), and wafers including low-k carbon containing films (such as Black Diamond™ and BLOk™). A patterned wafer type is a wafer which includes at least one film (oxide film 563 of FIG. 5D) disposed on the wafer surface which has been through lithographic and etching steps to form a circuit pattern. Circuit patterns and metal lines (film 561 of FIG. 5D) often contain copper. A patterned wafer type may possibly be visually distinguishable from the apparent circuit pattern on the surface. A stealth copper film wafer type contains a copper film (film 545 of FIG. 5B and FIG. 5C) disposed above the wafer substrate surface but beneath a second film. The stealth copper film might not be visible from a visual inspection.

Patterned wafer types and stealth copper film wafer types are stripped using a bead blasting technique in which all films disposed on the wafer surface are physically removed in a solid state. Because the removal is in a solid state, this alleviates the concern of bulk copper cross contamination between wafers. Low-k carbon containing film wafer types are stripped using a dry plasma etching technique.

FIG. 5A-5C illustrate various stripping methods for copper containing wafer types which utilize an analytical XRF measurement. FIG. 5A illustrates a stripping method for a copper containing surface film wafer type. In an exemplary embodiment, a copper containing surface film wafer type includes a silicon wafer 551 with a TaN film 553 disposed over the silicon wafer 551. A copper containing surface film 555 is disposed over the TaN film 553. The wafer surface is analytically measured with XRF at block 502 to determine a wafer type. At block 504 the XRF results are correlated with a copper containing wafer type. A visual inspection further indicates the wafer is a copper surface film wafer type. The copper containing surface film 555 is stripped at block 506 utilizing a dilute HNO3 solution to expose a TaN surface film 553. The wafer surface is then analytically measured with XRF at block 508 to determine if the wafer contains a second copper containing film below the exposed surface. At block 509 the XRF results are correlated with a Ta/TaN wafer type. Since the wafer does not contain a second copper containing film, the TaN barrier film 453 is then stripped at block 510 utilizing a mixed acid etchant such as a dilute HNO3:HF:HAc mixture or dilute HF:HCI mixture.

FIG. 5B illustrates a stripping method for a wafer type containing a copper containing surface film and a stealth copper film located beneath the surface. In an exemplary embodiment, similar to FIG. 5A, the wafer type includes a silicon wafer 551 with a TaN film 553 disposed over the silicon wafer 551, and a copper containing surface film 555 disposed thereon. The wafer type additionally includes TaN film 543, stealth copper film 545, and oxide film 547 disposed between the silicon wafer 551 and TaN film 553. The wafer surface is analytically measured with XRF at block 502 to determine a wafer type. At block 504 the XRF results are correlated with a copper containing wafer type. A visual inspection further indicates the wafer is a copper surface film wafer type. The copper containing surface film 555 is stripped at block 506 utilizing a dilute HNO3 mixture to expose a TaN surface film 553. The wafer surface is then analytically measured with XRF at block 508 to determine if the wafer contains a second copper containing film below the exposed surface. At block 509 the XRF results are correlated with a copper containing wafer type. A visual inspection further indicates the wafer is a copper stealth film wafer type. Since the wafer does contain a second copper containing film 545, the wafer is stripped using a bead blasting technique at block 520.

FIG. 5C illustrates a stripping method for a wafer type containing a stealth copper film located beneath the surface. In an exemplary embodiment, the wafer type includes a silicon wafer 551 with a TaN film 543 disposed over the silicon wafer 551, and a stealth copper film 545 disposed thereon. An oxide surface film 547 is disposed over the stealth copper film 545. The wafer surface is analytically measured with XRF at block 502 to determine a wafer type. At block 504 the XRF results are correlated with a copper containing wafer type. A visual inspection further indicates the wafer is a copper stealth film wafer type. Since the wafer contains a copper containing film 545 below the surface (copper stealth film), the wafer is stripped using a bead blasting technique at block 520.

FIG. 5D illustrates a stripping method for a copper containing patterned wafer type. In an exemplary embodiment, the wafer type includes a silicon wafer 551 with patterned oxide 563 and copper 561 films disposed thereon. The wafer surface is analytically measured with XRF at block 502 to determine a wafer type. At block 504 the XRF results are correlated with a copper containing wafer type. A visual inspection further indicates the wafer is a copper containing patterned wafer type. Since the wafer contains a patterned copper containing film 561, the wafer is stripped using a bead blasting technique at block 520.

Although the present invention has been described in language specific to structural features and/or methodological acts, it is to be understood that the invention defined in the appended claims is not necessarily limited to the specific features or acts described. The specific features and acts disclosed are instead to be understood as particularly graceful implementations of the claimed invention useful for illustrating the present invention.

What is claimed is:

1. A method for reclaiming a wafer comprising:
providing a wafer, said wafer having a film disposed over a surface of said wafer;
performing an analytical measurement of said wafer surface to determine a wafer type of said wafer;
correlating results of said analytical measurement with a wafer type;
stripping said film from said wafer, wherein said stripping method is determined by said wafer type;
performing a polishing operation on said wafer; and
performing a cleaning operation on said wafer.

2. The method of claim 1 wherein said analytical measurement is an XRF measurement.

3. The method of claim 2 further comprising reading a wafer ID and measuring a thickness of said wafer simultaneously with performing said XRF measurement.

4. The method of claim 1 wherein said wafer type is selected from the group consisting of copper film containing wafer type and non-copper film containing wafer type.

5. The method of claim 4 wherein said wafer is a copper film containing wafer type and said film is a copper containing surface film.

6. The method of claim 4 wherein said wafer is a copper film containing wafer type and said film is a copper containing film disposed below a second film.

7. The method of claim 4 wherein said wafer is a copper film containing wafer type and said wafer further comprises a Ta, TaN, oxide, or nitride film formed thereon.

8. The method of claim 4 wherein said wafer is a non-copper film containing wafer type and said film is an oxide, nitride, polysilicon, Ti, CoSi, Al, or W film formed thereon.

9. The method of claim 4 wherein said wafer is a non-copper film containing wafer type and said stripping method comprises:
exposing said wafer to O3 to remove any residual organic material;
removing said film from said wafer with a dilute HF solution, wherein said film is an oxide or nitride film;
rinsing said wafer; and
exposing said wafer to O3 to remove any residual oxide.

10. The method of claim 4 wherein said wafer is a non-copper film containing wafer type and said stripping comprises:
exposing said wafer to O3 to remove any residual organic material;
removing said film from said wafer with an HF containing solution, wherein said film is a Ta or TaN film;
rinsing said wafer; and
exposing said wafer to O3 to remove any residual oxide.

11. The method of claim 4 wherein said wafer is a copper film containing wafer type and said stripping comprises:
exposing said wafer to O3 to remove any residual organic material;
removing said film with a dilute HNO3 solution, wherein said film is a copper containing film;
rinsing said wafer; and
exposing said wafer to O3 to remove any residual oxide.

12. A method for stripping a wafer comprising:
providing a wafer, said wafer having a copper containing surface film stripping said copper containing surface film from said wafer to expose a second surface;
testing said wafer for a second copper containing film below said second surface; and
if said wafer contains a second copper containing film then bead blasting said wafer, if said wafer does not contain a second copper containing film then applying an acidic stripping solution to said wafer.

13. The method of claim 8 further comprising exposing said wafer to a rinse solution comprising a chelating agent after stripping said copper containing surface film.

14. The method of claim 11 wherein stripping said copper containing surface film comprises applying a dilute HNO3 solution to said wafer surface.

15. The method of claim 11 wherein applying an acidic stripping solution comprises applying a solution comprising HF and HCI to said wafer surface.

16. The method of claim 11 wherein applying an acidic stripping solution comprises applying a solution comprising HNO3, HF, and HAc to said wafer surface.

17. The method of claim 11 further comprising exposing said wafer to O3 to remove any residual organic material prior to stripping said copper containing surface film.

18. The method of claim 11 further comprising exposing said wafer to O3 to remove any residual oxide after applying an acidic stripping solution to said wafer.

19. A method for stripping a wafer comprising:
providing a wafer, said wafer having a copper containing film disposed over a surface of said wafer, said copper containing film being disposed below a second film;
performing an analytical measurement of said wafer surface to determine the presence of said copper containing film;
performing a visual inspection of said wafer surface; and
bead blasting said wafer to remove said copper containing film and said second film.

20. The method of claim 19 wherein said analytical measurement is an XRF measurement.
